(19) United States
(12) Patent Application Publication
(10) Pub. No.: US 2024/0312520 A1
(43) Pub. Date: Sep. 19, 2024

(54) THREE-DIMENSIONAL FLASH MEMORY HAVING STRUCTURE WITH EXTENDED MEMORY CELL AREA

(71) Applicant: IUCF-HYU (Industry University Cooperation Foundation Hanyang University), Seoul (KR)

(72) Inventor: Yun Heub Song, Seoul (KR)

(73) Assignee: IUCF-HYU (Industry University Cooperation Foundation Hanyang University), Seoul (KR)

(21) Appl. No.: 18/263,497

(22) PCT Filed: Nov. 26, 2021
(86) PCT No.: PCT/KR2021/017627

§ 371 Date: Jul. 28, 2023

(30) Foreign Application Priority Data
Feb. 2, 2021 (KR) 10-2021-0014855

(51) Int. Cl. G11C 16/04; H10B 43/10; H10B 43/27

(52) U.S. Cl. CPC G11C 16/0483; H10B 43/10; H10B 43/27

(57) ABSTRACT

A three-dimensional flash memory having a structure with an extended memory cell area, and a manufacturing method therefor are disclosed. According to one embodiment, a three-dimensional memory having a structure with an extended memory cell area comprises: a plurality of word lines stacked on a substrate in the vertical direction and extending in the horizontal direction; and at least one memory cell string, which passes through the plurality of word lines and is formed on the substrate to extend in the vertical direction, wherein the at least one memory cell string comprises a channel layer formed to extend in the vertical direction and a charge storage layer formed to encompass the channel layer, forms a plurality of memory cells corresponding to the plurality of word lines, and has a structure in which regions corresponding to the plurality of memory cells protrude in the horizontal direction.

### TECHNICAL FIELD

The following embodiments relate to a three-dimensional flash memory, and more particularly, to a technology for a three-dimensional flash memory having a structure with an extended memory cell area, and a method of manufacturing the same.

### BACKGROUND ART

Flash memory elements are electrically erasable programmable read only memories (EEPROMs), and the memories may be commonly used in, for example, computers, digital cameras, MP3 players, game systems, memory sticks, and the like. Such flash memory elements electrically control input/output of data by Fowler-Nordheim tunneling or hot electron injection.

In detail, referring to FIG. 1 illustrating an array of a three-dimensional flash memory according to the related art, the array of the three-dimensional flash memory may include a common source line CSL, a bit line BL, and a plurality of cell strings CSTR arranged between the common source line CSL and the bit line BL.

The bit lines are two-dimensionally arranged, and the plurality of cell strings CSTR are connected in parallel to the bit lines. The cell strings CSTR may be commonly connected to the common source line CSL. That is, the plurality of cell strings CSTR may be arranged between the plurality of bit lines and the one common source line CSL. In this case, a plurality of common source lines CSL may be provided, and the plurality of common source lines CSL may be arranged two-dimensionally. Here, the electrically same voltage may be applied to the plurality of common source lines CSL or each of the common source lines CSL may be also electrically controlled.

Each of the cell strings CSTR may include a ground selection transistor GST connected to the common source line CSL, a string selection transistor SST connected to the bit line BL, and a plurality of memory cell transistors MCT arranged between the ground and string selection transistors GST and SST. Further, the ground selection transistor GST, the string selection transistor SST, and the memory cell transistors MCT may be connected in series.

The common source line CSL may be commonly connected to sources of the ground selection transistors GST. In addition, a ground selection line GSL, a plurality of word lines WL0 to WL3, and a plurality of string selection lines SSL, which are arranged between the common source line CSL and the bit line BL, may be used as electrode layers of the ground selection transistor GST, the memory cell transistors MCT, and the string selection transistors SST. Further, each of the memory cell transistors MCT includes a memory element.

Meanwhile, in a three-dimensional flash memory according to the related art, in order to satisfy excellent performance and low price required by consumers, cells are vertically stacked, and thus the degree of integration increases.

For example, referring to FIG. 2 illustrating a structure of the three-dimensional flash memory according to the related art, the three-dimensional flash memory according to the related art is manufactured by arranging an electrode structure 215, in which interlayer insulating layers 211 and horizontal structures 250 are alternately and repeatedly formed, on a substrate 200. The interlayer insulating layers 211 and the horizontal structures 250 may extend in a first direction. The interlayer insulating layers 211 may be, for example, a silicon oxide film, and the lowermost interlayer insulating layer 211a among the interlayer insulating layers 211 may have a thickness lower than those of the other interlayer insulating layers 211. Each of the horizontal structures 250 may include first and second blocking insulating films 242 and 243 and an electrode layer 245. A plurality of the electrode structures 215 are provided, and the plurality of electrode structures 215 may be arranged to face each other in a second direction intersecting the first direction. The first and second directions may correspond to an X axis and a Y axis of FIG. 2, respectively. Trenches 240 spacing the plurality of electrode structures 215 apart from each other may extend between the plurality of electrode structures 215 in the first direction. Highly doped impurity areas may be formed in the substrate 200 exposed by the trenches 240, and thus the common source line CSL may be disposed. Although not illustrated, isolation insulating films filling the trenches 240 may be further arranged.

Vertical structures 230 passing through the electrode structures 215 may be arranged. As an example, in a plan view, the vertical structures 230 may be arranged in a matrix form while being aligned in the first and second directions. As another example, the vertical structures 230 may be aligned in the second direction and may be arranged in a zigzag form in the first direction. Each of the vertical structures 230 may include a protective film 224, a charge storage film 225, a tunnel insulating film 226, and a channel layer 227. As an example, the channel layer 227 may be disposed in a hollow tube shape therein, and in this case, a buried film 228 filling an inside of the channel layer 227 may be further disposed. A drain area D may be disposed on the channel layer 227 and a conductive pattern 229 may be formed on the drain area D and may be connected to the bit line BL. The bit line BL may extend in a direction intersecting the horizontal electrodes 250, for example, in the second direction. As an example, the vertical structures 230 aligned in the second direction may be connected to the one bit line BL.

The first and second blocking insulating films 242 and 243 included in the horizontal structures 250 and the charge storage film 225 and the tunnel insulating film 226 included in the vertical structures 230 may be defined as oxide-nitride-oxide (ONO) layers that are information storage elements of the three-dimensional flash memory. That is, some of the information storage elements may be included in the vertical structures 230, and the other thereof may be included in the horizontal structures 250. As an example, among the information storage elements, the charge storage film 225 and the tunnel insulating film 226 may be included in the vertical structures 230, and the first and second blocking insulating films 242 and 243 may be included in the horizontal structures 250. However, the present disclosure is not restricted or limited thereto, and the charge storage film 225 and the tunnel insulating film 226 defined as the ONO layer may be included only in the vertical structures 230.

Epitaxial patterns 222 may be arranged between the substrate 200 and the vertical structures 230. The epitaxial patterns 222 connect the substrate 200 and the vertical structures 230. The epitaxial patterns 222 may be in contact with at least one layer of the horizontal structures 250. That is, the epitaxial patterns 222 may be arranged in contact with a lowermost horizontal structure 250a. According to another embodiment, the epitaxial patterns 222 may be arranged in contact with a plurality of layers, for example, two layers, of the horizontal structures 250. Meanwhile, when the epitaxial patterns 222 are arranged in contact with the lowermost horizontal structure 250a, the lowermost horizontal structure 250a may be thicker than the other horizontal structures 250. The lowermost horizontal structure 250a in contact with the epitaxial patterns 222 may correspond to the ground selection line GSL of the array of the three-dimensional flash memory described with reference to FIG. 1, and the other horizontal structures 250 in contact with the vertical structures 230 may correspond to the plurality of word lines WL0 to WL3.

Each of the epitaxial patterns 222 has a recessed side wall 222a. Accordingly, the lowermost horizontal structure 250a in contact with the epitaxial patterns 222 is disposed along a profile of the recessed side wall 222a. That is, the lowermost horizontal structure 250a may be disposed in an inwardly convex shape along the recessed side walls 222a of the epitaxial patterns 222.

In the three-dimensional flash memory having such a structure, a cross-sectional area of a memory cell (the channel layer 227 and the charge storage film 225) is reduced due to a structure in which a cross-section area of a memory cell string 230 is reduced to improve the degree of integration, and thus reliability of the memory cell is degraded.

Accordingly, a technology for solving the above problem is required.

### DETAILED DESCRIPTION OF THE INVENTION

### Technical Problem

Embodiments propose a three-dimension flash memory having a structure in which areas of a memory cell string, which correspond to a plurality of memory cells, protrude in a horizontal direction to improve the degree of integration by reducing a cross sectional area of the memory cell string, and at the same time, to increase a cross-sectional area of the memory cells, and a method of manufacturing the same.

### Technical Solution

According to an embodiment, a three-dimensional flash memory having a structure with an extended memory cell area includes a plurality of word lines stacked in a vertical direction while extending on a substrate in a horizontal direction, and at least one memory cell string passing through the plurality of word lines and extending on the substrate in the vertical direction, the at least one memory cell string constituting a plurality of memory cells corresponding to the plurality of word lines while including a channel layer extending in the vertical direction and a charge storage layer formed to surround the channel layer, wherein the at least one memory cell string has a structure in which areas corresponding to the plurality of memory cells protrude in the horizontal direction.

According to an aspect, the at least one memory cell string may have a structure in which areas of the channel layer, which correspond to the plurality of memory cells, and areas of the charge storage layer, which correspond to the plurality of memory cells, protrude.

According to another aspect, the at least one memory cell string may have a structure in which remaining areas of the channel layer other than the areas corresponding to the plurality of memory cells and remaining areas of the charge storage layer other than the areas corresponding to the plurality of memory cells are recessed.

According to still another aspect, the areas of the charge storage layer, which correspond to the plurality of memory cells, may be connected to each other by the remaining areas of the charge storage layer.

According to yet another aspect, the areas of the channel layer, which correspond to the plurality of memory cells, may be areas of the channel layer, which correspond to the plurality of word lines, and the areas of the charge storage layer, which correspond to the plurality of memory cells, may be areas of the charge storage layer, which correspond to the plurality of word lines.

According to yet another aspect, the remaining areas of the channel layer may be areas of the channel layer, which correspond to a plurality of interlayer insulating layers interposed between the plurality of word lines, and the remaining areas of the charge storage layer may be areas of the charge storage layer, which correspond to the plurality of interlayer insulating layers.

According to yet another aspect, a cross-sectional size of areas of the at least one memory cell string, which correspond to the plurality of word lines, may be greater than a cross-sectional size of areas of the at least one memory cell string, which correspond to the plurality of interlayer insulating layers.

### Advantageous Effects of the Invention

Embodiments propose a three-dimensional flash memory having a structure in which areas of a memory cell string, which correspond to a plurality of memory cells, protrude in a horizontal direction, and a method of manufacturing the same, so that the degree of integration may be improved by reducing a cross sectional area of the memory cell string, and at the same time, a cross-sectional area of the memory cells may increase.

### DESCRIPTION OF THE DRAWINGS

FIG. 1 is a schematic circuit diagram illustrating an array of a three-dimensional flash memory according to the related art;

FIG. 2 is a perspective view illustrating a structure of the three-dimensional flash memory according to the related art;

FIG. 3 is a side cross-sectional view illustrating a three-dimensional flash memory according to an embodiment;

FIG. 4 is a plan view along line A-A′ illustrated in FIG. 3;

FIG. 5 is a plan view along line B-B′ illustrated in FIG. 3;

FIG. 6 is a flowchart illustrating a method of manufacturing the three-dimensional flash memory according to the embodiment; and

FIGS. 7A to 7F are side cross-sectional views illustrating the three-dimensional flash memory to describe the manufacturing method illustrated in FIG. 6.

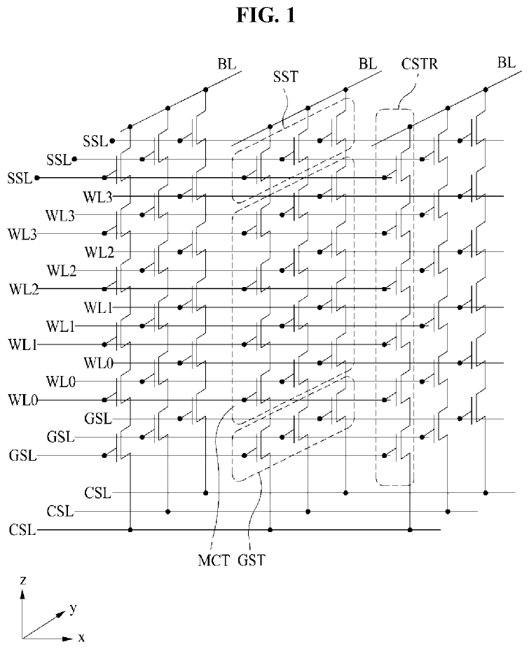

### BEST MODE

Hereinafter, embodiments will be described in detail with reference to the accompanying drawings. However, the present disclosure is not restricted or limited by the embodiments. Further, the same reference numerals in each drawing indicate the same components.

Further, terms used in the present specification are used to properly express the embodiments of the present disclosure, and the terms may change depending on the intention of a user or an operator or customs in the field to which the present disclosure belongs. Therefore, definitions of the present terms should be made based on the contents throughout the present specification.

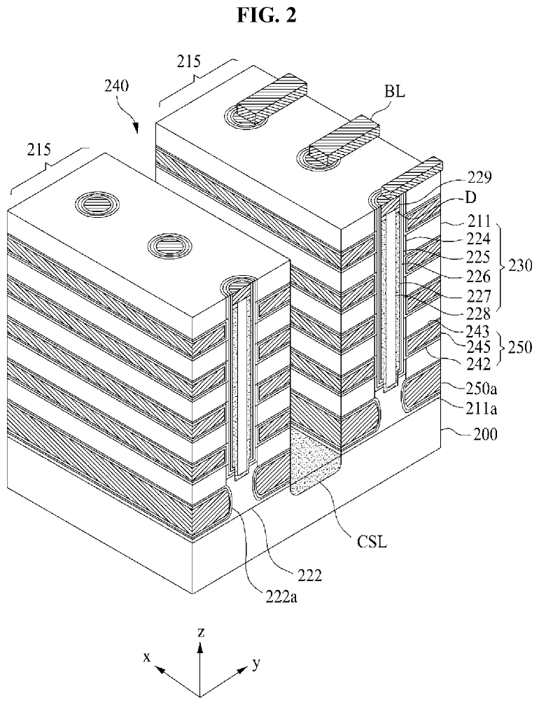

Hereinafter, in a side cross-sectional view illustrating a three-dimensional flash memory, for convenience of description, a three-dimensional flash memory will be illustrated and described while components such as a source line positioned below a plurality of memory cell strings are omitted. However, the three-dimensional flash memory, which will be described below, is not restricted and limited thereto, and may further include an additional component on the basis of a structure of the three-dimensional flash memory illustrated with reference to FIG. 2.

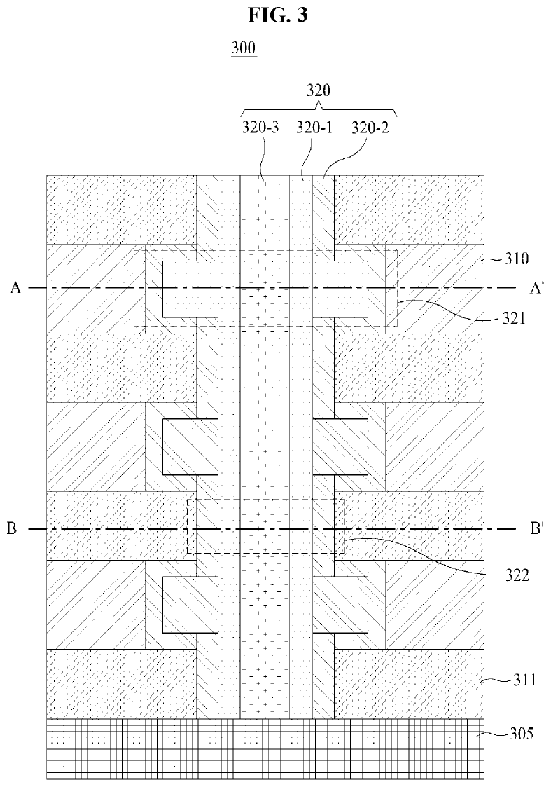

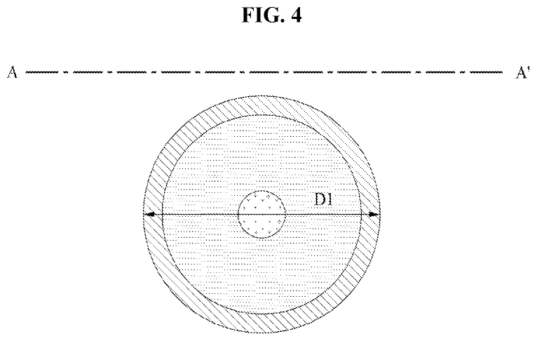

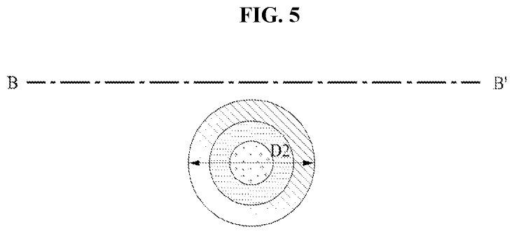

FIG. 3 is a side cross-sectional view illustrating a three-dimensional flash memory according to an embodiment, FIG. 4 is a plan view along line A-A′ illustrated in FIG. 3, and FIG. 5 is a plan view along line B-B′ illustrated in FIG. 3.

Referring to FIGS. 3 to 5, a three-dimensional flash memory 300 according to the embodiment includes a plurality of word lines 310 and at least one memory cell string 320.

The plurality of word lines 310 are vertical direction sequentially stacked in a vertical direction while extending on a substrate 305 in a horizontal direction, are made of a conductive material such as W (tungsten), Ti (titanium), Ta (tantalum), Cu (copper), Mo (molybdenum), Ru (ruthenium), or Au (gold) (including all metallic materials capable of forming ALD in addition to the above-described metallic materials), apply voltages to memory cells corresponding thereto, and perform a memory operation (a reading operation, a program operation, an erasure operation, or the like). A plurality of interlayer insulating layers 311 made of an insulating material may be interposed between the plurality of word lines 310.

A string selection line (SSL) may be disposed at a top of the plurality of word lines 310, and a ground selection line (GSL) may be disposed at a bottom thereof.

The at least one memory cell string 320 includes a channel layer 320-1 and a charge storage layer 320-2 while passing through the plurality of word lines 310 and extending on the substrate 305 in a vertical direction, and thus may constitute a plurality of memory cells corresponding to the plurality of word lines 310.

The charge storage layer 320-2 is a component that traps charges or holes by voltages applied through the plurality of word lines 310 or maintains states of charges (e.g., polarization states of charges) while extending to surround the channel layer 320-1 and may serve as a data storage in the three-dimensional flash memory 300. As an example, an oxide-nitride-oxide (ONO) layer or a ferroelectric layer may be used as the charge storage layer 320-2. The charge storage layer 320-2 is not restricted or limited to the extending to surround the channel layer 320-1 and may also have a structure separated for each memory cell while surrounding the channel layer 320-1.

The channel layer 320-1 is a component that performs a memory operation by voltages applied through the plurality of word lines 310, the SSL, the GSL, and a bit line and may be formed of monocrystalline silicon or polycrystalline silicon.

The channel layer 320-1 has a macaroni shape with an empty inside and thus may include an oxide buried film 320-3 therein.

In particular, the at least one memory cell string 320 may have a structure in which areas 321 corresponding to the plurality of memory cells protrude in a horizontal direction. Hereinafter, the plurality of memory cells include areas of the channel layer 320-1, which correspond to the plurality of word lines 310 and areas of the charge storage layer 320-2, which correspond to the plurality of word lines 310, and thus the areas 321 corresponding to the plurality of memory cells may refer to areas corresponding to the plurality of word lines 310.

In more detail, the at least one memory cell string 320 may have a structure in which areas of the channel layer 320-1, which correspond to the plurality of memory cells (areas corresponding to the plurality of word lines 310), and areas of the charge storage layer 320-2, which correspond to the plurality of memory cells (areas corresponding to the plurality of word lines 310), protrude.

Further, the at least one memory cell string 320 may have a structure in which remaining areas 322 of the whole areas other than the areas 321 corresponding to the plurality of memory cells are recessed (a structure in which remaining areas of the channel layer 320-1 other than areas corresponding to the plurality of memory cells and remaining areas of the charge storage layer 320-2 other than the areas corresponding to the plurality of memory cells are recessed).

Here, the remaining areas 322 are areas corresponding to the plurality of interlayer insulating layers 311, and thus a structure in which the remaining areas 322 are recessed may refer to a structure in which the areas 322 corresponding to the plurality of interlayer insulating layers 311 are recessed.

That is, the at least one memory cell string 320 may have an uneven shape in which a cross-sectional size D1 of the areas 321 corresponding to the plurality of memory cells (the areas corresponding to the plurality of word lines 310) as in FIG. 4 is greater than a cross-sectional size D2 of the remaining areas 322 (the areas corresponding to the plurality of interlayer insulating layers 311) as in FIG. 5.

Thus, since horizontal scaling of the memory cell string 320 is promoted, the degree of integration may be improved, and at the same time, only a cross-sectional area of the memory cell may be increased.

In this case, the areas of the charge storage layer 320-2, which correspond to the plurality of memory cells (the areas corresponding to the plurality of word lines 310), may be connected to each other by the remaining areas of the charge storage layer 320-2 (the areas corresponding to the plurality of interlayer insulating layers 311). In other words, even under the restriction that the at least one memory cell string 320 has the above-described protruding structure, the charge storage layer 320-2 may not be implemented as a plurality of charge storage layers 320-2 that are separated for each of the plurality of memory cells and spaced apart from each other but may be implemented integrally. Accordingly, a process of manufacturing the at least one memory cell string 320 including the charge storage layer 320-2 may be simplified as compared to a case in which the charge storage layer 320-2 is implemented as a plurality of charge storage layers that are separated and spaced apart from each other.

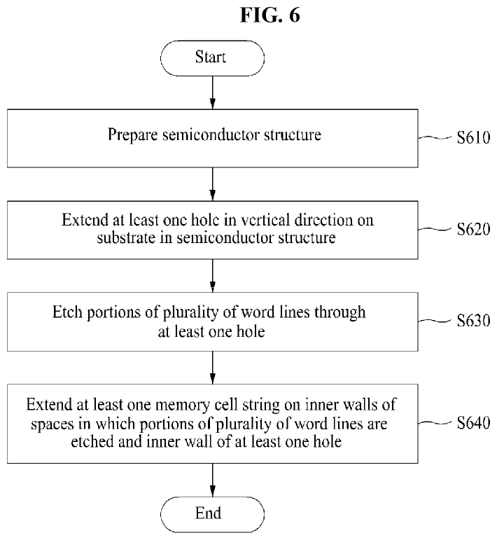

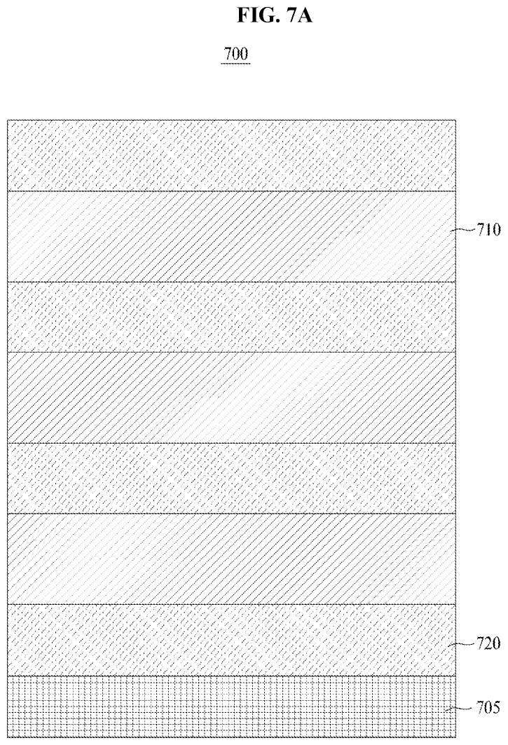

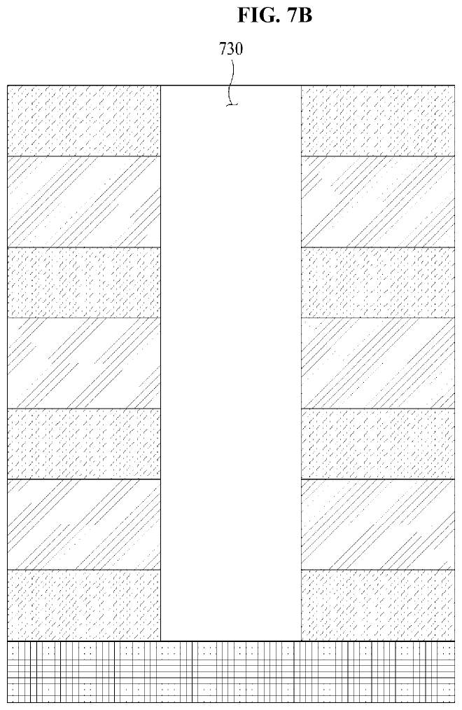

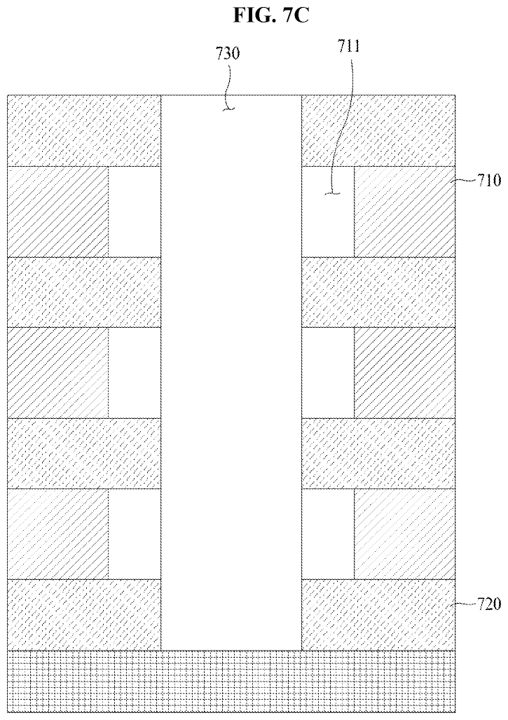

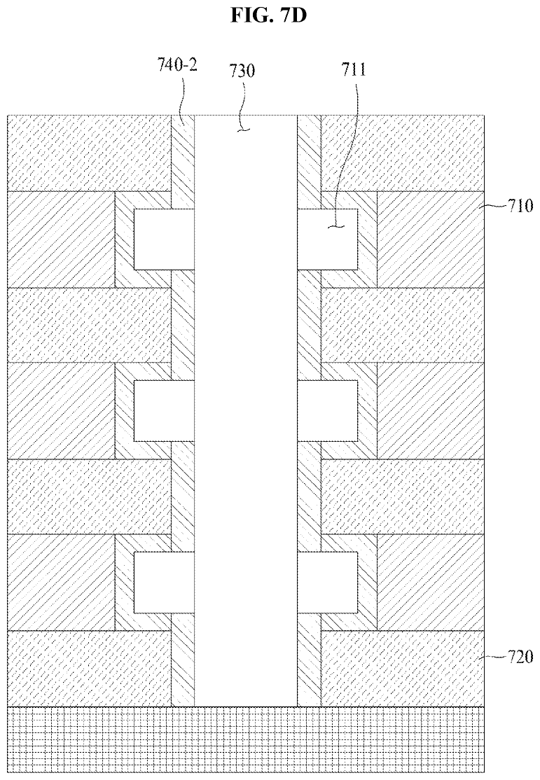

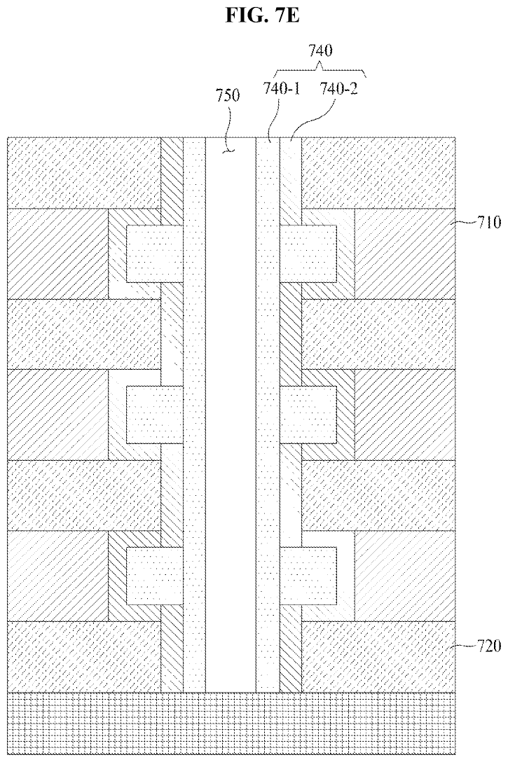

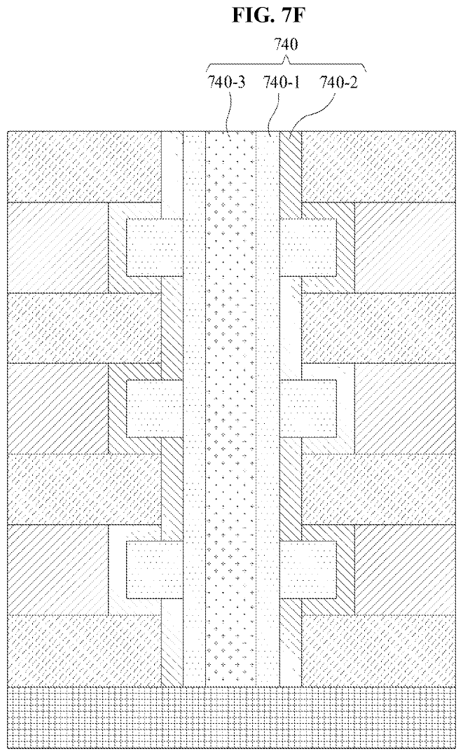

FIG. 6 is a flowchart illustrating a method of manufacturing the three-dimensional flash memory according to the embodiment, and FIGS. 7A to 7F are side cross-sectional views illustrating the three-dimensional flash memory to describe the manufacturing method illustrated in FIG. 6.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIGS. 3 to 5.

Referring to FIG. 6, in operation S610, a manufacturing system according to the embodiment may prepare a semiconductor structure 700 as in FIG. 7A.

Here, the semiconductor structure 700 may include a plurality of word lines 710 stacked in a vertical direction while extending on a substrate 705 in a horizontal direction and a plurality of interlayer insulating layers 720 interposed between the plurality of word lines 710.

Next, in operation S620, as in FIG. 7B, the manufacturing system may extend at least one hole 730 in a vertical direction on the substrate 705 in the semiconductor structure 700.

Next, in operation 630, as in FIG. 7C, the manufacturing system may etch portions of the plurality of word lines 710 through the at least one hole 730. Accordingly, spaces 711 in which the portions of the plurality of word lines 710 are etched may be secured.

Next, in operation S640, the manufacturing system may extend at least one memory cell string 740 on inner walls of the spaces 711 in which the portions of the plurality of word lines 710 are etched and an inner wall of the at least one hole 730. The at least one memory cell string 740 may constitute the plurality of memory cells corresponding to the plurality of word lines 710 while including a channel layer 740-1 and a charge storage layer 740-2.

In particular, in operation S640, the manufacturing system may extend at least one memory cell string 740 so that areas corresponding to the plurality of memory cells have a protrusion structure.

In more detail, in operation S640, the manufacturing system may extend the charge storage layer 740-2 on the inner walls of the spaces 711 in which the portions of the plurality of word lines 710 are etched and the inner wall of the at least one hole 730 as in FIG. 7D so that areas of the charge storage layer 740-2, which correspond to the plurality of memory cells (areas corresponding to the plurality of word lines 710), have a protrusion structure. Thereafter, the manufacturing system may extend the channel layer 740-1 on the inner walls of the spaces 711 in which the charge storage layer 740-2 extends and the inner wall of the at least one hole 730 as in FIG. 7E so that areas of the channel layer 740-1, which correspond to the plurality of memory cells (areas corresponding to the plurality of word lines 710), have a protrusion structure.

In this case, in operation S640, the manufacturing system may extend the charge storage layer 740-2 on the inner walls of the spaces 711 in which the portions of the plurality of word lines 710 are etched and the inner wall of the at least one hole 730 as in FIG. 7D so that remaining areas of the charge storage layer 740-2 other than the areas corresponding to the plurality of memory cells (areas corresponding to the plurality of interlayer insulating layers 720) have a recessed structure. Thereafter, the manufacturing system may extend the channel layer 740-1 on the inner walls of the spaces 711 in which the charge storage layer 740-2 extends and the inner wall of the at least one hole 730 as in FIG. 7E so that remaining areas of the channel layer 740-1 other than the areas corresponding to the plurality of memory cells (areas corresponding to the plurality of interlayer insulating layers 720), have a recessed structure.

That is, through operation S640, through the manufacturing system, a cross-sectional size of areas of the at least one memory cell string 740, which correspond to the plurality of word lines 710, may be formed greater than a cross-sectional size of areas of the at least one memory cell string 740, which correspond to the plurality of interlayer insulating layers 720.

Further, in operation S640, the manufacturing system may extend the charge storage layer 740-2 so that the areas of the charge storage layer 740-2, which correspond to the plurality of memory cells (areas corresponding to the plurality of word lines 710), are connected to each other by the remaining areas of the charge storage layer 740-2 (areas corresponding to the plurality of interlayer insulating layers 720). This means that the charge storage layer 740-2 is integrally formed, and thus process complexity of operation S640 may be remarkably reduced.

Thereafter, although not illustrated in FIG. 6 as a separate operation, the manufacturing system may fill a buried film 730-3 in an inner space 750 of the channel layer 740-1 as in FIG. 7F and thus manufacture the three-dimensional flash memory.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory having a structure with an extended memory cell area, the three-dimensional flash memory comprising:
a plurality of word lines stacked in a vertical direction while extending on a substrate in a horizontal direction; and
at least one memory cell string passing through the plurality of word lines and extending on the substrate in the vertical direction, the at least one memory cell string constituting a plurality of memory cells corresponding to the plurality of word lines while including a channel layer extending in the vertical direction and a charge storage layer formed to surround the channel layer,
wherein the at least one memory cell string has a structure in which areas corresponding to the plurality of memory cells protrude in the horizontal direction.

2. The three-dimensional flash memory of claim 1, wherein the at least one memory cell string has a structure in which areas of the channel layer, which correspond to the plurality of memory cells, and areas of the charge storage layer, which correspond to the plurality of memory cells, protrude.

3. The three-dimensional flash memory of claim 2, wherein the at least one memory cell string has a structure in which remaining areas of the channel layer other than the areas corresponding to the plurality of memory cells and remaining areas of the charge storage layer other than the areas corresponding to the plurality of memory cells are recessed.

4. The three-dimensional flash memory of claim 3, wherein the areas of the charge storage layer, which correspond to the plurality of memory cells, are connected to each other by the remaining areas of the charge storage layer.

5. The three-dimensional flash memory of claim 3, wherein the areas of the channel layer, which correspond to the plurality of memory cells, are areas of the channel layer, which correspond to the plurality of word lines, and
the areas of the charge storage layer, which correspond to the plurality of memory cells, are areas of the charge storage layer, which correspond to the plurality of word lines.

6. The three-dimensional flash memory of claim 5, wherein the remaining areas of the channel layer are areas of the channel layer, which correspond to a plurality of interlayer insulating layers interposed between the plurality of word lines, and
the remaining areas of the charge storage layer are areas of the charge storage layer, which correspond to the plurality of interlayer insulating layers.

7. The three-dimensional flash memory of claim 6, wherein a cross-sectional size of areas of the at least one memory cell string, which correspond to the plurality of word lines, is greater than a cross-sectional size of areas of the at least one memory cell string, which correspond to the plurality of interlayer insulating layers.
